(19) United States
(12) Patent Application Publication
(10) Pub. No.: US 2006/0161277 A1
(43) Pub. Date: Jul. 20, 2006

(54) Portable personal pocket-sized audio sound equalizer to be used in-line with headphones or speakers

(76) Inventor: Daniel A. Robinson, New York, NY (US)

Correspondence Address: Daniel A. Robinson, 687 West 204th Street, # 5E, New York, NY, 10034, US

(21) Appl. No.: 10/950,372

(22) Filed: Jan. 19, 2005

(51) Int. Cl. G06F 17/00; H03G 5/00

(52) U.S. Cl. 700/94; 381/103

(57) ABSTRACT

A portable, in-line audio equalizer is disposed between the audio source and the headphones/speakers. The personal, pocket-sized audio equalizer includes an A/D converter for changing the analog input into digital form, followed by a twelve-band digital equalizer. The output from the digital equalizer is converted back into analog form and passes through a variable amplifier to form the equalized output signal.

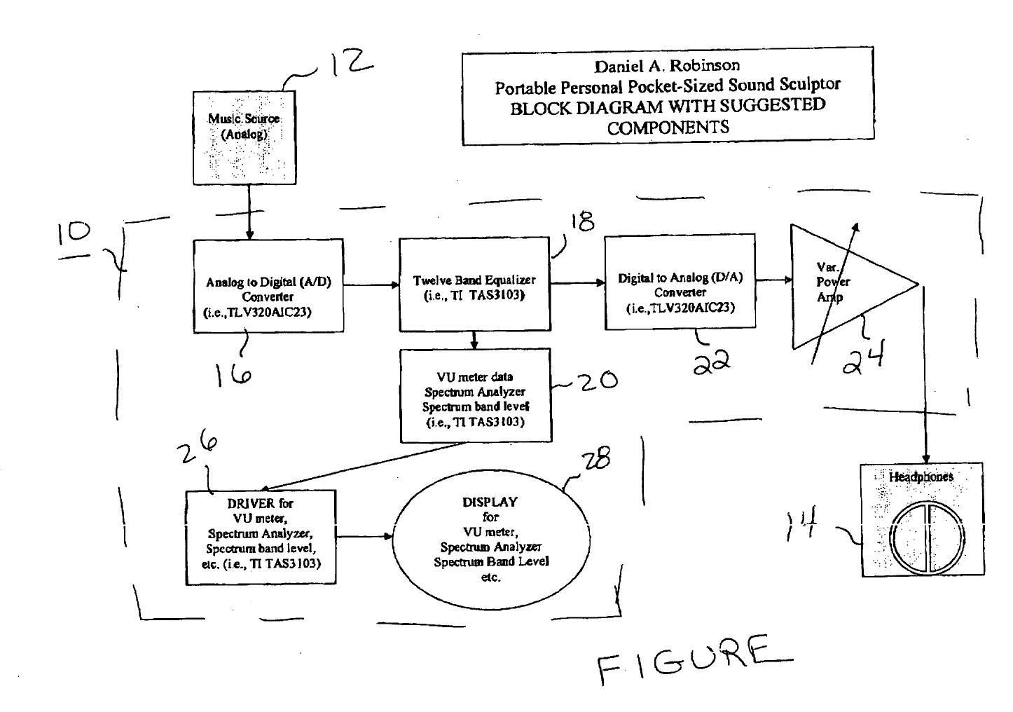

### CROSS-REFERENCE TO RELATED APPLICATION

This application claims the benefit of U.S. Provisional Application No. ______, filed ______.

### TECHNICAL FIELD

The present invention relates to a sound equalizer and, more particularly, to a portable sound equalizer for use in-line with either headphones or speakers.

### BACKGROUND OF THE INVENTION

Large sound equalizers have been developed to address problems associated with different audio frequencies exhibiting a different “loudness” component. Without equalizers, one's listening experience may be hampered by certain frequencies “sticking out” and distorting the sound. Low, mid or high notes of music, for example, or important frequencies of the spoken word may be lost or distorted.

While large sound equalizers solve these problems in a home setting (with a presumably stationary audio system), the equalization problem remains unsolved with respect to portable listening devices. Moreover, the problems are exacerbated by hearing-impaired individuals, since hearing aids function to enhance all sounds, but cannot address the dynamically changing aspects of music or the spoken word.

### BRIEF DESCRIPTION OF THE DRAWING

The sole FIGURE illustrates a personal, portable sound equalizer for use as an in-line device with either headphones or speakers, in accordance with the present invention.

### DETAILED DESCRIPTION

In accordance with the present invention, an in-line audio equalizer has been developed that is small enough to be carried with and coupled to a portable listening device (in-line with either headphones or speakers). The FIGURE illustrates the inventive audio equalizer 10, showing an analog input source 12 (for example, a music source) being applied to equalizer 10, with the output then coupled (in this example) into headphones 14. Audio equalizer 10 is shown as comprising an A/D converter 16 coupled to analog input source 10, where the digital output from A/D converter 16 is applied as an input to an exemplary equalizer 18, in this case a twelve band equalizer. A VU meter 20 may be coupled to equalizer 18 and used to record the equalizing data associated with the input signal. The output from equalizer 18 is thereafter applied as an input to a D/A converter 22 and fed to a variable power amplifier 24. In accordance with the present invention, the output from variable power amplifier 24 is applied as the equalized input to headphones 14. Also illustrated in the FIGURE is a driver 26 for powering the components of the inventive equalizer and a display 28 for illustrated the recorded readings associated with VU meter 20.

Because of its ability to increase power in different audio frequencies, the inventive in-line equalizer can drive headphones of any type. The equalizer functions to sculpt sounds so that the audio is as clear as possible, with the result being a pocket-sized device.

What is claimed is:

1. An in-line audio equalizer for use with a portable listening device, the equalizer comprising:
an input A/D converter for converting an analog input audio file into a digital representation thereof;
a digital equalizer responsive to the output from the input A/D converter to perform an equalizing function on the separate digital components;
an output D/A converter for translating the equalized, digital signal into an analog representation; and
a variable power amplifier, coupled to the output of the output D/A converter for providing an equalized, audio signal that may then be coupled into the portable listening device.

2. An in-line audio equalizer as defined in claim 1 wherein the digital equalizer comprises a twelve-band equalizer.

3. An in-line audio equalizer as defined in claim 1 wherein the equalizer further comprises a VU meter for providing a spectrum analyzer and a spectrum band level, with a driver associated with the VU meter.

4. An in-line audio equalizer as defined in claim 3 wherein the equalizer further comprises a display for the VU meter.

5. An in-line audio equalizer as defined in claim 1 wherein the portable listening device comprises a CD player.

6. An in-line audio equalizer as defined in claim 1 wherein the portable listening device comprises an MP3 player.

7. An in-line audio equalizer as defined in claim 1 wherein the portable listening device comprises a DVD player.

8. An in-line audio equalizer as defined in claim 1 wherein the output of the variable power amplifier is coupled into headphones associated with the portable listening device.

9. An in-line audio equalizer as defined in claim 1 wherein the output of the variable power amplifier is coupled into speakers associated with the portable listening device.
